(19) United States
(12) Patent Application Publication
(10) Pub. No.: US 2022/0190457 A1
(43) Pub. Date: Jun. 16, 2022

(54) SUBSTRATE INTEGRATED WAVEGUIDE SIGNAL LEVEL CONTROL ELEMENT AND SIGNAL PROCESSING CIRCUITRY

(71) Applicant: SONY SEMICONDUCTOR SOLUTIONS CORPORATION, Atsugi-shi (JP)

(72) Inventors: Kamal SAMANTA, Basingstoke (GB); John Christopher CLIFTON, Basingstoke (GB)

(73) Assignee: SONY SEMICONDUCTOR SOLUTIONS CORPORATION, Atsugi-shi (JP)

(21) Appl. No.: 17/441,852

(22) PCT Filed: Feb. 28, 2020
(86) PCT No.: PCT/GB2020/050480

§ 371 Date: Sep. 22, 2021

(30) Foreign Application Priority Data
Mar. 29, 2019 (GB) 1904452.8

(51) Int. Cl. H01P 3/12; H01P 1/22; H01P 5/18; H03H 7/25

(52) U.S. Cl. CPC H01P 3/121; H01P 1/222; H03H 7/255; H01P 5/18; H01P 3/122

(57) ABSTRACT

A signal level control element comprises a substrate having conductive formations defining a substrate integrated wave-guide arrangement disposed at least partly within the substrate; the substrate integrated waveguide arrangement providing a quadrature hybrid coupler having first and second pairs of signal ports, such that a signal introduced to a port of one pair of the first and second pairs is provided with equal amplitude but a 90 degree phase difference to both ports of the other pair of the first and second pairs; in which a port of the first pair is configured to receive an input signal and the other port of the first pair is configured to provide an output signal; and termination circuitry connected to the ports of the second pair, the termination circuitry providing, for each port of the second pair, a respective termination having a variable impedance dependent upon a respective control signal.

### BACKGROUND

### Field

This disclosure relates to substrate integrated waveguide signal level control elements and signal processing circuitry.

### Description of Related Art

The “background” description provided herein is for the purpose of generally presenting the context of the disclosure. Work of the presently named inventors, to the extent it is described in this background section, as well as aspects of the description which may not otherwise qualify as prior art at the time of filing, is neither expressly or impliedly admitted as prior art against the present disclosure.

Microwave or other high frequency (up to THz) signal processing components make use of waveguide formations to provide signal processing functions.

### SUMMARY

The present disclosure provides a signal level control element comprising:

a substrate having conductive formations defining a substrate integrated waveguide arrangement disposed at least partly within the substrate;

the substrate integrated waveguide arrangement providing a quadrature hybrid coupler having first and second pairs of signal ports, such that a signal introduced to a port of one pair of the first and second pairs is provided with equal amplitude but a 90 degree phase difference to both ports of the other pair of the first and second pairs;

in which a port of the first pair is configured to receive an input signal and the other port of the first pair is configured to provide an output signal; and

termination circuitry connected to the ports of the second pair, the termination circuitry providing, for each port of the second pair, a respective termination having a variable impedance dependent upon a respective control signal.

The present disclosure also provides signal processing circuitry comprising a substrate carrying one or more signal processing components, in which the substrate provides the substrate for such a signal level control device, the signal level control device being connected to one or more of the signal processing components.

The present disclosure also provides a mobile communications base station, a radar apparatus, an Internet of Things (IoT) device, a satellite payload device or a mobile telecommunications device or handset comprising such signal processing circuitry.

Further respective aspects and features of the present disclosure are defined in the appended claims.

It is to be understood that both the foregoing general description and the following detailed description are exemplary, but are not restrictive, of the present technology.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIG. 1 schematically illustrates a stage in the fabrication of a so-called fence-post substrate integrated waveguide (SIW);

FIG. 2 schematically illustrates a later stage in the fabrication of the fence-post SIW;

FIG. 3 schematically illustrates a stage in the fabrication of a so-called trench-filled SIW;

FIG. 4 schematically illustrates a later stage in the fabrication of the trench-filled SIW;

FIGS. 5 and 6 are schematic cross sections through the example SIW arrangements of FIGS. 1-4;

FIG. 7 schematically represents a quadrature hybrid coupler arranged as a signal level control element;

FIGS. 8A-8C and 9 schematically represented quadrature hybrid couplers fabricated using fence-post (FIG. 8A), slot-filled (FIG. 8B) and trench-filled (FIGS. 8C and 9) SIW techniques;

FIG. 10 schematically illustrates a signal level control element using an SIW quadrature hybrid coupler;

FIGS. 11-14 schematically illustrate variations of signal level control elements;

FIG. 15 schematically represents signal processing circuitry; and

FIG. 16 schematically illustrates a device or apparatus.

### DESCRIPTION OF THE PREFERRED EMBODIMENTS

Referring now to the drawings, examples of so-called substrate integrated waveguide (SIW) components will now be described.

These components are used in, for example, applications involving frequency ranges from microwave to Terahertz (THz) ranges to provide, for example, electronically continuously variable signal level controlling applications. In this context “microwaves” have a wavelength ranging from (say) 1 m (corresponding to a frequency of 300 MHz) to 1 mm (corresponding to a frequency of 300 GHz). THz radiation has a frequency range generally above 300 GHz. But it will be appreciated that the particular labels applied to these frequency ranges are not exactly defined, nor are the labels technically significant in themselves. In the context of components fabricated on a substrate such as those described below, the relevant wavelength range in order to achieve reasonably dimensioned components might be, for example, from tens of GHz up to 100-200 GHz or beyond into the 300 GHz+range. The present techniques are applicable to these ranges, even if not explicitly stated in respect of each individual feature. But the present techniques are applicable outside of these ranges as well.

SIW components are characterised by fabrications which penetrate the substrate and which are filled with a conducting material such as metal in order to define sidewall formations. In the present examples they extend parallel to the plane of the waveguide and are defined by conductive formations.

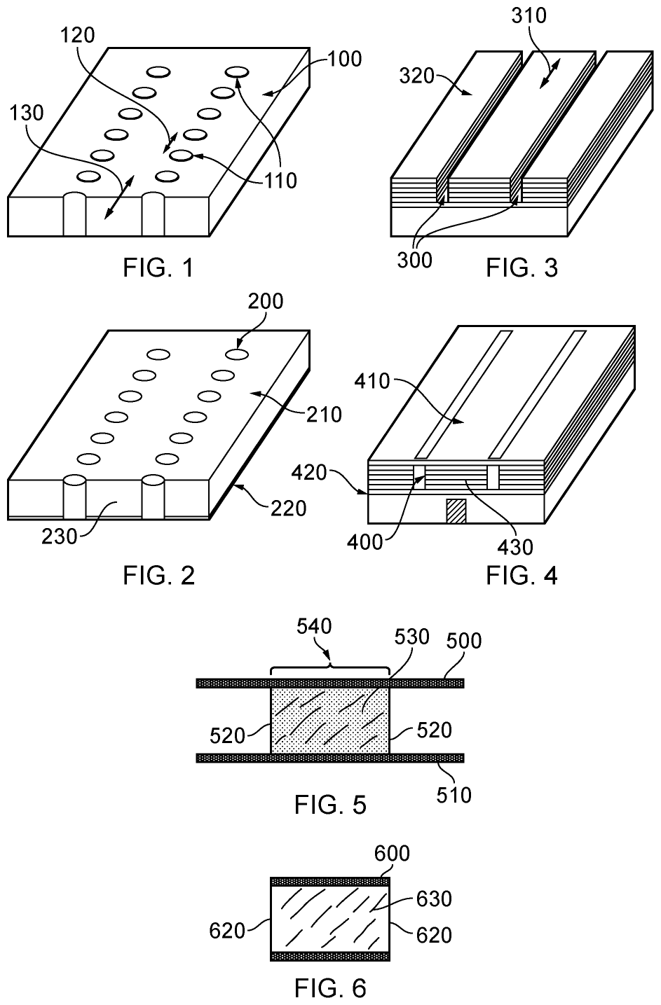

FIG. 1 shows a substrate 100 which might be a single or multi-layer structure forming a dielectric substrate in which so-called fence-posts 110 are fabricated. The fence-posts are formed by boring, drilling, etching or punching holes through or into the substrate 100 and are generally close enough together (represented by a distance 120 in a waveguide propagation direction 130) so as to provide a sidewall which appears continuous to the microwave or THz frequency in use. For example, the distance 120 may be 0.1 x the wavelength in use, for example 200 μm in a component intended for use at 40 GHz. A typical depth in, say, a 40 GHz component would be 50 μm to 600 μm and a typical hole diameter in such a component would be 100 um. In some examples, rather than using cylindrical holes, elongate (in the plane of the substrate and along the waveguide direction) formations such as spaced-apart slots can be used as the “fence posts”. Such arrangements can be referred to as slot-filled SIW waveguides.

These example parameters indicate that as the nominal operating frequency increases, the pitches and radii of fabricated vias forming the fence posts or slots can become very fine (including for so-called double row fence post techniques), and can therefore become difficult to realise using conventional fabrication techniques. As a result, at higher frequencies, so-called trench-filled sidewall techniques (see FIG. 3 described below) can be more appropriate for realizing a high performance component.

At a subsequent stage in fabrication, the fence-posts 110 or slots are filled (or at least substantially filled) with metal or another conducting material to form a set of two or more conductive formations 200 spaced apart in the waveguide direction 130.

In general terms, the fence posts can be fabricated (for example for a PCB, LTCC, LCP, HTCC, high resistive Si, or glass substrate—see below—where the holes might be fabricated by a mechanical or laser drilling process) for all of the layers, or on a layer-by layer basis, for example where the substrate is such that the holes are formed by an etching process (as an example, a multilayer substrate).

Upper 210 and lower 220 conductive layers parallel to the plane of the substrate are formed, so that the metal-filled fence-posts form conductive sidewall formations defining to waveguide sidewalls extending within the substrate along the waveguide direction between the upper and lower conductive layers 210, 220. Note that the lower layer may be an outermost lower layer or may be an internal layer (which may indeed have already been formed before the fence-posts were fabricated). Note also that the terms “upper” and “lower” refer here to the orientation in the drawing and do not imply any required orientation of the component in the use. It is noted, however, that in the case of a substrate such as a printed circuit board, the holes 110 might be formed by drilling from an outer face of the printed circuit board, which would then imply that the upper layer 210 is formed on that outer layer.

Using these techniques, the upper and lower conductive layers and the conductive sidewall formations together surround a waveguide region 230 of the substrate.

A similar arrangement is used in FIG. 3 in which so-called trench formations 300, representing longitudinal cut-away regions which are continuous in the waveguide direction 310 are formed in a dielectric substrate 320. These can be formed by, for example, etching or milling. The trenches are filled (or at least substantially filled) with conducting material such as metal to form at each side a conductive sidewall formation 400 extending within the substrate along the waveguide direction representing a conductive formation which is continuous in the waveguide direction. As with FIG. 2, upper 410 and lower 420 conductive layers are formed parallel to the plane of the substrate. Once again, the upper and lower conductive layers and the conductive sidewall formations 400 together define a waveguide region 430 of the substrate.

FIGS. 5 and 6 are schematic cross sections through the example SIW arrangements of FIGS. 1-4. These show the upper 500, 600 and lower 510, 610 conductive layers and the conductive sidewall formations 520, 620 which may be fence-post or trench-filled, in each case surrounding a waveguide region 530, 630. At least the waveguide region 530, 630 is within the substrate. In the arrangement of FIG. 5, the upper and lower conductive layers can extend beyond the lateral extent 540 of the waveguide region 530 for ease of fabrication, whereas in FIG. 6 the upper and lower conductive layers do not extend beyond the lateral extent of the waveguide region 630.

Note that in a practical implementation of FIGS. 5 and 6, dielectric material will extend outside of the waveguide region as shown; it is not drawn in these Figures for clarity of the diagrams.

As mentioned, the substrate may be a planar substrate formed of one or more substrate layers of a dielectric material. In the context of an SIW component of the type discussed above, there are two or more metal layers separated by one or more dielectric layers, and the first and second (upper and lower) conductive layers defining the SIW component are formed as at least respective portions of the two or more metal layers.

Suitable substrates can include a dielectric substrate, such as a substrate selected from the list consisting of: a printed circuit board (PCB); a low-temperature co-fired ceramic (LTCC) substrate;, a high-temperature co-fired ceramic (HTCC)substrate; a liquid crystal polymer (LCP) substrate and a benzocyclobutene (BCB) substrate. However, it will be appreciated that other substrate materials may be used.

In other examples, a semiconductor substrate such as a silicon (Si), high resistive Si, gallium arsenide (GaAs), gallium nitride (GaN) or indium phosphide (InP) substrate (on and in which conductive formations are fabricated) can be used.

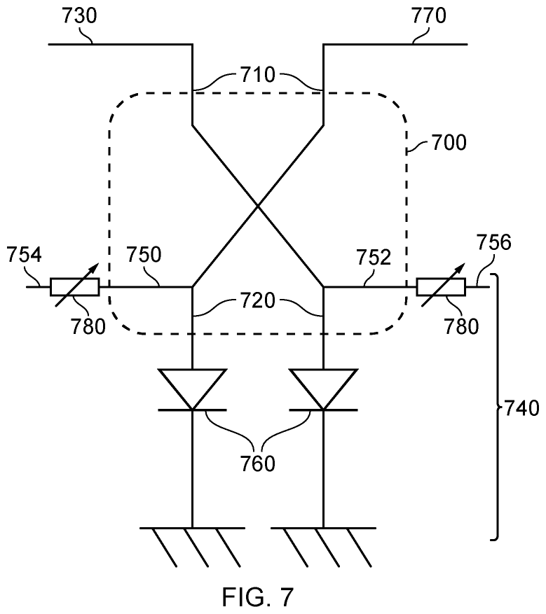

As further background to the present techniques, FIG. 7 schematically represents a quadrature hybrid coupler and a pair of diodes arranged as a high frequency (for example covering microwave to THz ranges as discussed above) signal level control element.

A quadrature hybrid coupler is a device in which (at least in the present context) a pair of waveguides are arranged with respect to one another so as to couple radiation between the two waveguides at a coupling region. A property of this type of coupler is that the coupler has first and second pairs of signal ports, such that a signal introduced into a port of one pair is provided with equal amplitude but a 90° phase difference to both ports of the other pair.

In FIG. 7, the coupler is represented by a portion 700. The first pair of signal ports comprises a pair 710 of ports and the second pair of ports comprises a pair 720 of ports. A signal introduced into one of the first pair of signal ports, for example a port 730 will, in the absence of the other components shown in FIG. 7, emerge equally at the second pair of signal ports 720 but with a 90° phase difference. The arrangement is symmetrical so that injection of a signal into one of the second pair 720 of signal ports will cause it to emerge with equal amplitude and a 90° phase difference at the first pair 710 of signal ports.

In the context of operation as a signal level control element, termination circuitry 740 is connected to the ports of one of the pairs of signal ports (which may be referred to as the second pair for the sake of discussion). The termination circuitry provides, for each port of the second pair, a respective termination having a variable impedance depended upon a respective control signal 750, 752. In the present example, the termination circuitry may comprise so-called PIN diodes 760. This type of diode is formed with a wide and doped intrinsic (I) semiconductor region between a p-type region (P) and an n-type region (N), so that the name “PIN” implies an ordering of these three regions. These diodes have a characteristic that their impedance varies with current flow when the diodes are forward-biased. Therefore, the impedance of the termination circuitry can be varied by varying the control current provided at the ports 750, 752.

In operation, if the impedance of each of the diodes 760 is arranged (by means of setting an appropriate value of the control current) to equal the impedance looking from the hybrid coupler ports which they terminate, there is a minimum output power (constructive addition) at one of the first pair of ports. Bearing in mind that the two signals that are being reflected at those ports are 90° out of phase (having passed once through the quadrature hybrid coupler) and are now reflected back for a second pass through the quadrature hybrid coupler, this means that at an input port 730 the reflected components will be 180° out of phase and will substantially cancel out. Therefore, attenuation, as between the input port 730 and the output port 770 is greatest when the impedance of the diodes 760 equals the impedance looking into the hybrid coupler ports 720. This is referred to as a maximum attenuation, not in the sense that no more signal could possibly be attenuated, but in the sense that it is a greater attenuation than an attenuation obtainable with that particular apparatus using a different termination circuitry impedance. Away from that maximum, a variable attenuation can be achieved by varying the impedance of the diodes 760.

In at least some example arrangements, better operation (for example, a greater maximum attenuation and isolation between input and output ports) can be obtained by matching the impedance at the second pair of ports 720. Steps which can be taken to achieve or assist with this can include (a) using a pair of diodes fabricated together or at least from a common fabrication batch; (b) providing one or two trimmer components such as variable resistances 780 between input ports 754, 756 and the ports 750, 752 to allow calibration to be performed so that the effect of the control signals at the port 750, 752 can be matched to one another; and (c) providing equal control signals to each of the control signal ports.

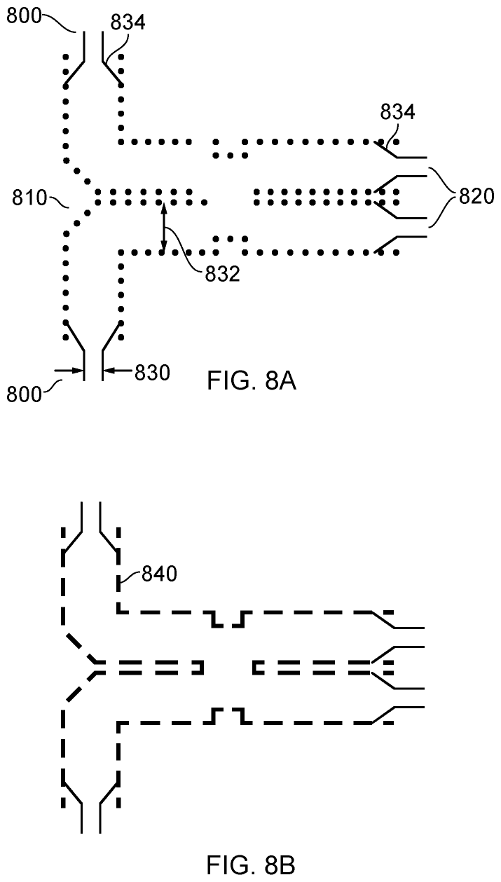

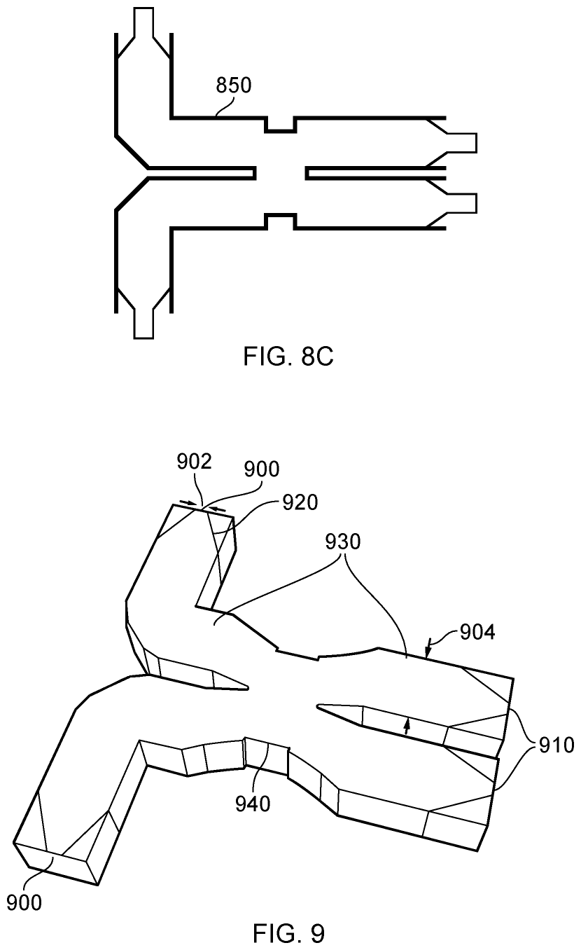

Quadrature hybrid couplers can be formed using SIW components. FIGS. 8A-8C and 9 schematically represented such couplers fabricated using fence-post (FIG. 8A), slot-filled (FIG. 8B) and trench-filled (FIGS. 8C and 9) techniques respectively. Control and termination components are not shown on FIGS. 8A-8C and 9. In FIG. 8A, shown in schematic plan view, the first pair 800 of signal ports are provided as so-called microstrip waveguide formations or transmission lines which meet at an SIW waveguide coupling region 810 before splitting back out into microstrip waveguide formations to form the second pair 820 of signal ports. The microstrip transmission lines are formed as a strip of conductive material disposed parallel to the plane of the substrate with respect to a conductive layer forming a ground plane (that is to say, no sidewall formations are provided).

FIG. 8B shows a similar schematic example using elongate formations (slots) 840 define the sides of the SIW waveguide formations. Other aspects and geometry are similar to those shown in FIG. 8A.

In the trench-filled example of FIGS. 8C and 9, (where FIG. 8C is shown in a schematic plan view and FIG. 9 is shown in a schematic isometric projection view), the SIW side walls are defined by conductor-filled trenches 850, but other aspects of FIG. 8C are similar to the geometry of FIG. 8A. Again microstrip signal ports 900, 910 represents the first and second pairs of signal ports respectively. A tapered region at each port 920 interfaces between the microstrip connection and portions 930 of SIW waveguide which meet at a coupling region 940.

The coupling region in each case represents a region at which two or more SIW waveguides are linked.

With regard to the interface between the microstrip and SIW waveguides, the strip of conductive material forming the microstrip transmission line has a first width 830, 902; the two or more substrate integrated waveguides have a second width 832, 904 different to the first width (for example, greater than the first width); and one or both of the strip of conductive material and the substrate integrated waveguides comprises a transitional portion 834, 920 to transition between the first width of the strip of conductive material and the second width of the two or more substrate integrated waveguides. Ports of the SIW device can be connected to microstrip lines or coplanar-waveguides.

Note that in each of the schematic examples of FIGS. 8A-8C, the walls of the SIW waveguides can be seen to extend beyond the extend at which the SIW formation meets the tapered portion 834.

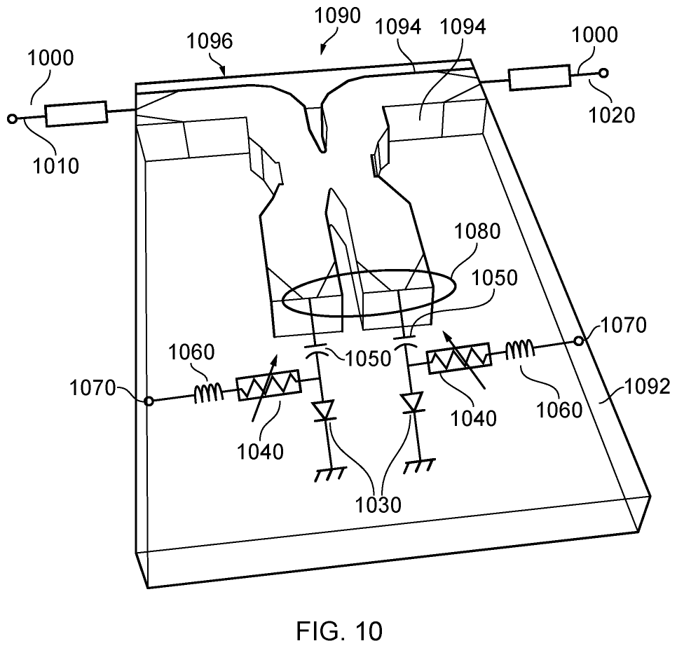

FIG. 10 schematically illustrate a signal control element using an SIW quadrature hybrid coupler. In FIG. 10, the example of FIG. 9 is used, but the techniques are equally applicable to the example of FIGS. 8A or 8B. A first pair of ports 1000 provide an input and an output port. For example, the input port might be a port 1010 drawn to the left of the diagram and the output port might be a port 1020 drawn to the right of the diagram, but it is noted that the arrangement is entirely symmetrical left-right as drawn.

PIN diodes 1030 form the termination circuitry, in association with trimming components 1040 and, in this example, capacitors 1050 and inductors 1060. The capacitors 050 are for passing RF (radio frequencies, or in the present context alternating signals) but blocking DC (direct current signals) from propagating towards the hybrid coupler, whereas the inductors 1060 are considered to function in the opposite way, passing DC but blocking RF to propagate towards the DC or control circuits. The impedance at each of the second pair 1080 of ports is dependent upon control signals at control signal inputs 1070. Therefore, the termination circuitry in this example comprises a diode such as a PIN diode associated with each port of the second pair and biased by the respective control signal so as to vary its impedance in response to the control signal.

FIG. 10 therefore illustrates an example of a signal level control element 1090 comprising a substrate 1092 having conductive formations 1094 defining a substrate integrated waveguide arrangement 1096 disposed (as discussed with reference to FIGS. 5 and 6 above) at least partly within the substrate 1092. The substrate integrated waveguide arrangement provides a quadrature hybrid coupler having first 1000 and second 1080 pairs of signal ports, such that a signal introduced to a port of one pair of the first and second pairs is provided with equal amplitude but a 90° phase difference to both ports of the other pair of the first and second pairs. A port 1010 of the first pair 1000 is configured to receive an input signal. The other port 1020 of the first pair 1000 is configured to provide an output signal. Termination circuitry including the diodes 1030 and ancillary components as shown is connected to the ports of the second pair 1080. The termination circuitry provides, for each port of the second pair, a respective termination having a variable impedance dependent upon a respective control signal (at each of the ports 1070).

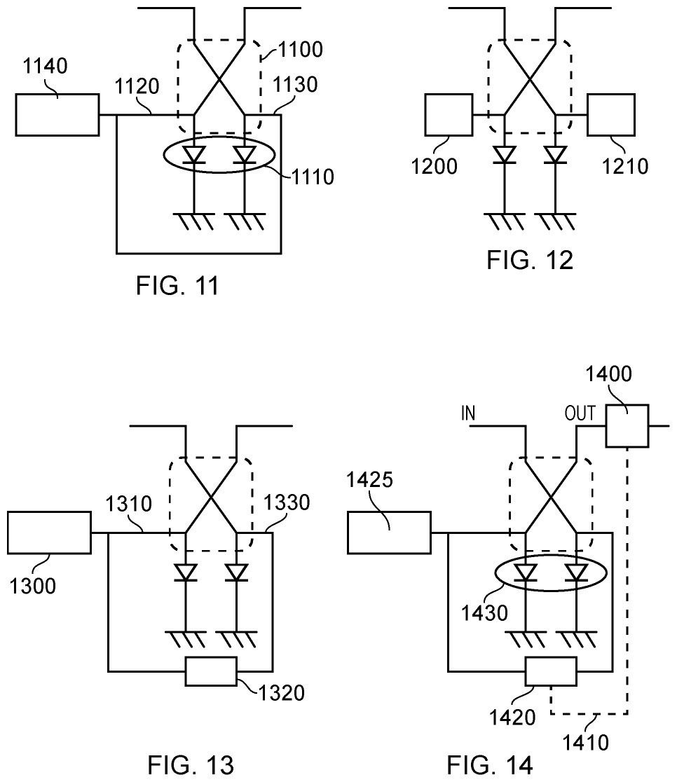

FIGS. 11-14 schematically illustrate variations of signal level control elements using the techniques shown in FIG. 10. Here, the “base” signal level control element is illustrated by a quadrature hybrid coupler 1100 and a pair 1110 of diodes providing at least a part of the termination circuitry and which are subject to control by signals provided to control signal inputs 1120, 1130. This simplified representation will be used in FIGS. 12-14 as well. It is assumed that depending on the frequency of operation and the performance of diodes trimming components are provided (though not explicitly shown) where appropriate.

In FIG. 11, control circuitry 1140 provides the control signals to the inputs 1120, 1130 to obtain a desired attenuation or adjustment of the signal and in particular, in this example, provides the same control signal to each of the inputs 1120, 1130. So, although the control signals can be different (as shown schematically in FIG. 12 in which respective control circuitry is 1200, 1210 provide (at least potentially) different control signals to the inputs 1120, 1130, in FIG. 11 the control signals are identical as between the inputs 1120, 1130, so that FIG. 11 shows an example circuitry to provide a single input control signal to the termination circuitry to provide the respective control signal to each port of the second pair.

A further possible arrangement is shown in FIG. 13, in which control circuitry 1300 generator control signal which is supplied equally to one input 1310 but via circuitry 1320 to the other input 1330. The circuitry 1320 can provide an external calibration separates to that provided by the trimming components discussed above so as to aim to equalise the impedance matching of the diodes in the termination circuitry.

In FIG. 14, an output power monitor 1400 detects the attenuation of the circuitry and uses this determination to generate a control signal 1410 to control calibration circuitry 1420 so as to adjust (relative to a common control signal generated by control circuitry 1425) the relative control signals applied to the two diodes 1430 so as to increase the maximum degree of isolation and attenuation obtainable with the apparatus.

Therefore, FIG. 14 provides an example using control circuitry 1420, 1400 configured to detect a signal level of the output signal and to detect whether a relative variation of the respective control signals which control the termination of the ports of the second pair provides an increase in the detected signal level.

In each case, the control signal(s) can be variable or static (or at least relatively slowly changing) so that the signal level control element acts as one of: an attenuator, such as a continuously variable attenuator, configured to attenuate the output signal in response to the respective control signals; and a modulator configured to modulate the output signal in response to respective time-varying control signals.

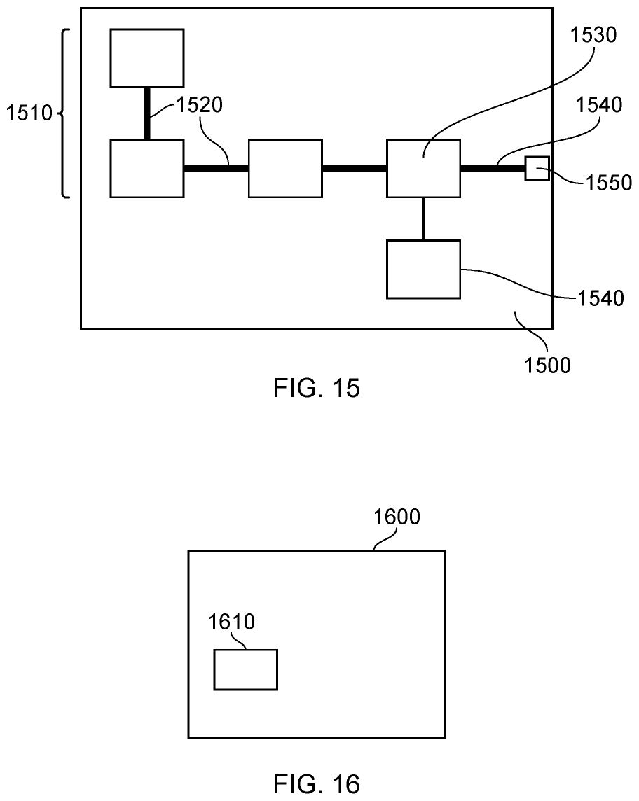

FIG. 15 is a schematic plan view of signal processing circuitry comprising a dielectric or semiconductor substrate 1500 carrying one or more signal processing components 1510 linked by planar transmission line (microstrip or coplanar-waveguide) formations 1520 in which the substrate 1500 provides a substrate for a signal level control device 1530, optionally under the control of control circuitry 1540, the signal level control device being connected to one or more of the signal processing components. In the example shown, an output signal waveguide 1540 of the signal level control device is connected to an output port 1550 such as a coaxial or waveguide socket.

The arrangement of FIG. 15 can be used as (or as a part 1610 of) a device or apparatus 1600 of FIG. 16, such as one or more of a mobile communications base station, a radar apparatus, an Internet of Things (IoT) device, a satellite payload device, a mobile telecommunications device or handset or the like.

It will be apparent that numerous modifications and variations of the present disclosure are possible in light of the above teachings. It is therefore to be understood that within the scope of the appended clauses, the technology may be practised otherwise than as specifically described herein.

It will be appreciated that the above description for clarity has described embodiments with reference to different functional units, circuitry and/or processors. However, it will be apparent that any suitable distribution of functionality between different functional units, circuitry and/or processors may be used without detracting from the embodiments. Described embodiments may be implemented in any suitable form including hardware, software, firmware or any combination of these. Described embodiments may optionally be implemented at least partly as computer software running on one or more data processors and/or digital signal processors. The elements and components of any embodiment may be physically, functionally and logically implemented in any suitable way. Indeed the functionality may be implemented in a single unit, in a plurality of units or as part of other functional units. As such, the disclosed embodiments may be implemented in a single unit or may be physically and functionally distributed between different units, circuitry and/or processors.

Although the present disclosure has been described in connection with some embodiments, it is not intended to be limited to the specific form set forth herein. Additionally, although a feature may appear to be described in connection with particular embodiments, one skilled in the art would recognize that various features of the described embodiments may be combined in any manner suitable to implement the technique.

Respective aspects and features are defined by the following numbered clauses:

1. A signal level control element comprising:

a substrate having conductive formations defining a substrate integrated waveguide arrangement disposed at least partly within the substrate;

the substrate integrated waveguide arrangement providing a quadrature hybrid coupler having first and second pairs of signal ports, such that a signal introduced to a port of one pair of the first and second pairs is provided with equal amplitude but a 90 degree phase difference to both ports of the other pair of the first and second pairs;

in which a port of the first pair is configured to receive an input signal and the other port of the first pair is configured to provide an output signal; and

termination circuitry connected to the ports of the second pair, the termination circuitry providing, for each port of the second pair, a respective termination having a variable impedance dependent upon a respective control signal.

2. A signal level control element according to clause 1, in which:

the substrate is a planar substrate having one or more substrate layers;

the conductive formations define two or more linked substrate integrated waveguides extending in a waveguide direction parallel to the plane of the substrate and each having, with respect to the waveguide direction:

first and second conductive layers parallel to the plane of the substrate, and

conductive sidewall formations defining two waveguide side walls extending within the substrate along the waveguide direction between the upper and lower conductive layers;

the first and second conductive layers and the conductive sidewall formations together surrounding a waveguide region of the substrate.

3. A signal level control element according to clause 2, in which the sidewall formations for a given waveguide side wall comprise one of:

(i) two or more conductive formations spaced apart in the waveguide direction;

(ii) a conductive formation which is continuous in the waveguide direction.

4. A signal level control element according to any one of the preceding clauses, in which the substrate is formed of one or more layers of a dielectric material.
5. A signal level control device according to clause 4, in which:

the substrate comprises a dielectric substrate having two or more metal layers separated by one or more dielectric layers; and

the first and second conductive layers defining the substrate integrated waveguide arrangement are formed as at least respective portions of the two or more metal layers.

6. A signal level control device according to clause 5, in which the substrate comprises a dielectric substrate selected from the list consisting of:

(i) a printed circuit board;

(ii) a low-temperature co-fired ceramic (LTCC) substrate;

(iii) a high temperature co-fired ceramic (HTCC) substrate;

(iv) a liquid crystal polymer (LCP) substrate;

(v) a benzocyclobutene (BCB) substrate; and

(vi) a glass substrate

7. A signal level control device according to any one of clauses 1 to 3, in which the substrate comprises a semiconductor substrate.
8. A signal level control device according to clause 7, in which the semiconductor substrate is a silicon (Si) substrate, a high resistive Si substrate, a GaAs substrate, a GaN substrate or an InP substrate.
9. A signal level control element according to clause 2, comprising, at each port of the quadrature hybrid coupler, a portion of microstrip waveguide formed as a strip of conductive material disposed parallel to the plane of the substrate with respect to a conductive layer forming a ground plane.
10. A signal level control element according to clause 9, in which:

the strip of conductive material has a first width;

the two or more substrate integrated waveguides have a second width different to the first width;

one or both of the strip of conductive material and the substrate integrated waveguides comprises a transitional portion to transition between the first width of the strip of conductive material and the second width of the two or more substrate integrated waveguides.

11. A signal level control element according to any one of the preceding clauses, in which the termination circuitry comprises a diode associated with each port of the second pair and biased by the respective control signal so as to vary its impedance in response to the control signal.
12. A signal level control element according to any one of the preceding clauses, comprising circuitry to provide a single input control signal to the termination circuitry to provide the respective control signal to each port of the second pair.
13. A signal level control element according to any one of the preceding clauses, comprising control circuitry configured to detect a signal level of the output signal and to detect whether a relative variation of the respective control signals which control the termination of the ports of the second pair provides an increase in the detected signal level.
14. A signal level control element according to any one of the preceding clauses, in which the signal level control element acts as one of:

an attenuator configured to attenuate the output signal in response to the respective control signals; and

a modulator configured to modulate the output signal in response to respective time-varying control signals.

15. Signal processing circuitry comprising a dielectric or semiconductor substrate carrying one or more signal processing components, in which the dielectric substrate provides the substrate for a signal level control device according to any one of clauses 1 to 3, the signal level control device being connected to one or more of the signal processing components.
16. A mobile communications base station, a radar apparatus, an Internet of Things (IoT) device, a satellite payload device or a mobile telecommunications device or handset comprising signal processing circuitry according to clause 15.

1. A signal level control element, comprising:
a substrate having conductive formations defining a substrate integrated waveguide arrangement disposed at least partly within the substrate, the substrate integrated waveguide arrangement providing a quadrature hybrid coupler having first and second pairs of signal ports, such that a signal introduced to a port of one pair of the first and second pairs is provided with equal amplitude but a 90 degree phase difference to both ports of the other pair of the first and second pairs, wherein in which a port of the first pair is configured to receive an input signal and the other port of the first pair is configured to provide an output signal; and
termination circuitry connected to the ports of the second pair, the termination circuitry providing, for each port of the second pair, a respective termination having a variable impedance dependent upon a respective control signal.

2. The signal level control element according to claim 1, wherein:
the substrate is a planar substrate having one or more substrate layers;
the conductive formations define two or more linked substrate integrated waveguides extending in a waveguide direction parallel to the plane of the substrate and each having, with respect to the waveguide direction:
first and second conductive layers parallel o the plane of the substrate, and
conductive sidewall formations defining two waveguide side walls extending within the substrate along the waveguide direction between the upper and lower conductive layers; and
the first and second conductive layers and the conductive sidewall formations together surrounding a waveguide region of the substrate.

3. The signal level control element according to claim 2, wherein the sidewall formations for a given waveguide side wall comprise one of:
(i) two or more conductive formations spaced apart iii the waveguide direction; and
(ii) a conductive formation which is continuous in the waveguide direction,

4. The signal level control element according to claim 1, wherein the substrate is formed of one or more layers of a dielectric material.

5. The signal level control device according to claim 4, wherein:
the substrate comprises a dielectric substrate having two or more metal layers separated by one or more dielectric layers; and
the first and second conductive layers defining the substrate integrated waveguide arrangement are formed as at least respective portions of the two or more metal layers.

6. The signal level control device according to claim 5, wherein the substrate comprises a dielectric substrate being one of:
(i) a printed circuit board;
(ii) a low-temperature co-fired ceramic (LTCC) substrate;
(iii) a high temperature co-fired ceramic (HTCC) substrate;
(iv) a liquid crystal polymer (LCP) substrate;
(v)) a benzocyclobutene (BCB) substrate; and
(vi) a Glass substrate

7. The signal level control device according to claim 1, wherein the substrate comprises a semiconductor substrate.

8. The signal level control device according to claim 7, wherein the semiconductor substrate is a silicon (Si) substrate, a high resistive Si substrate, a GaAs substrate, a GaN substrate, or an InP substrate.

9. The signal level control element according to claim 2, further comprising, at each port of the quadrature hybrid coupler, a portion of microstrip waveguide formed as a strip of conductive material disposed parallel to the plane of the substrate with respect to a conductive layer forming a ground plane.

10. The signal level control element according to claim 9, wherein:
the strip of conductive material has a first width;
the two or more substrate integrated waveguides have a second width different to the first width: and
one or both of the strip of conductive material and the substrate integrated waveguides comprises a transitional portion to transition between the first width of the strip of conductive material and the second width of the two or more substrate integrated waveguides.

11. The signal level control element according to claim 1, wherein the termination circuitry comprises a diode associated with each port of the second pair and biased by the respective control signal so as to vary its impedance in response to the control signal.

12. The signal level control element according to claim 1, further comprising circuitry configured to provide a single input control signal to the termination circuitry to provide the respective control signal to each port of the second pair.

13. The signal level control element according to claim 1, further comprising control circuitry configured to detect a signal level of the output signal and to detect whether a relative variation of the respective control signals which control the termination of the ports of the second pair provides an increase in the detected signal level.

14. The signal level control element according to claim 1, wherein the signal level control element acts as one of:
an attenuator configured to attenuate the output signal in response to the respective control signals; and
a modulator configured to modulate the output signal in response to respective time-varying control signals.

15. Signal processing circuitry, comprising a substrate carrying one or more signal processing components, wherein the substrate provides the substrate for a signal level control device according to claim 1, the signal level control device being connected to one or more of the signal processing components.

16. A mobile communications base station, a radar apparatus, an Internet of Things (IoT) device, a satellite payload device, or a mobile telecommunications device or handset, comprising:
the signal processing circuitry according to claim 15.
